(19) United States
(12) Patent Application Publication
(10) Pub. No.: US 2012/0063086 A1
(43) Pub. Date: Mar. 15, 2012

(54) ELECTRONIC DEVICE

(75) Inventor: YAO-TING CHANG, Tu-Cheng (TW)

(73) Assignee: HON HAI PRECISION INDUSTRY CO., LTD., Tu-Cheng (TW)

(21) Appl. No.: 12/910,853

(22) Filed: Oct. 24, 2010

(30) Foreign Application Priority Data
Sep. 15, 2010 (TW) 99131329

(51) Int. Cl. H05K 7/20

(52) U.S. Cl. 361/695

(57) ABSTRACT

An electronic device includes a chassis, a blower, a first block, and a second block. The chassis includes a top surface and a bottom surface parallel to the top surface. The blower is received in the chassis. The blower includes an upper surface, a lower surface parallel to the upper surface, and an outlet defined between the upper surface and the lower surface. The first block is disposed between the upper surface and the top surface to seal a gap between the upper surface and the top surface. The second block is disposed between the lower surface and the bottom surface to seal a gap between the lower surface and the bottom surface.

### BACKGROUND

1. Technical Field

The present disclosure relates to electronic devices, and particularly, to an electronic device having blocks.

2. Description of Related Art

In recent years, electronic devices, such as computer systems, have been developed to operate at ever higher speeds, and thus generate a lot of heat during operation. Usually, heat dissipation apparatuses such as motor driven fans and blowers are applied in the electronic devices for dissipating the heated air. However, heated air expelled by the dissipation apparatuses may flow back into the device through gaps existing between the dissipation apparatuses and an enclosure of the electronic device.

Therefore, an electronic device overcoming the limitations described is desired.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is a schematic view of an electronic device according to a first embodiment.

FIG. 2 is an isometric view of a blower, a first block and a second block of the electronic device of FIG. 1.

FIG. 3 is a top view of FIG. 2.

FIG. 4 is a schematic view of an electronic device according to a second embodiment.

### DETAILED DESCRIPTION

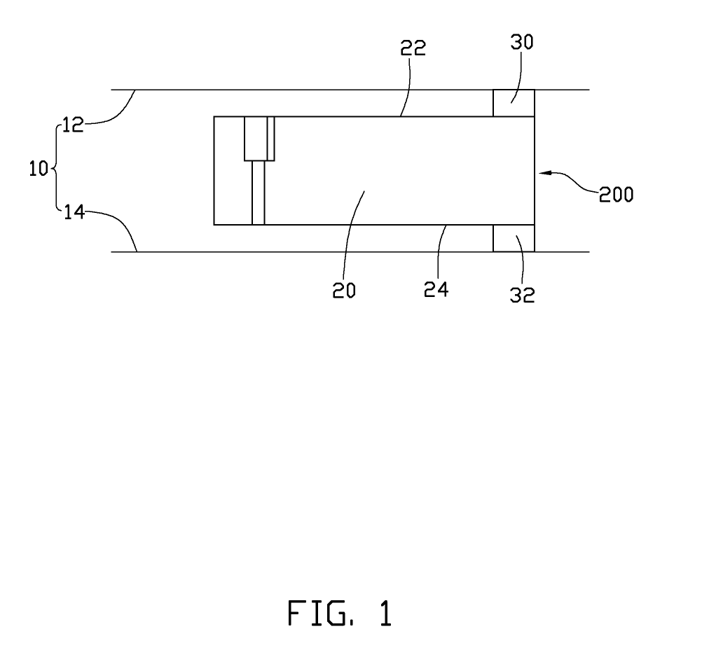

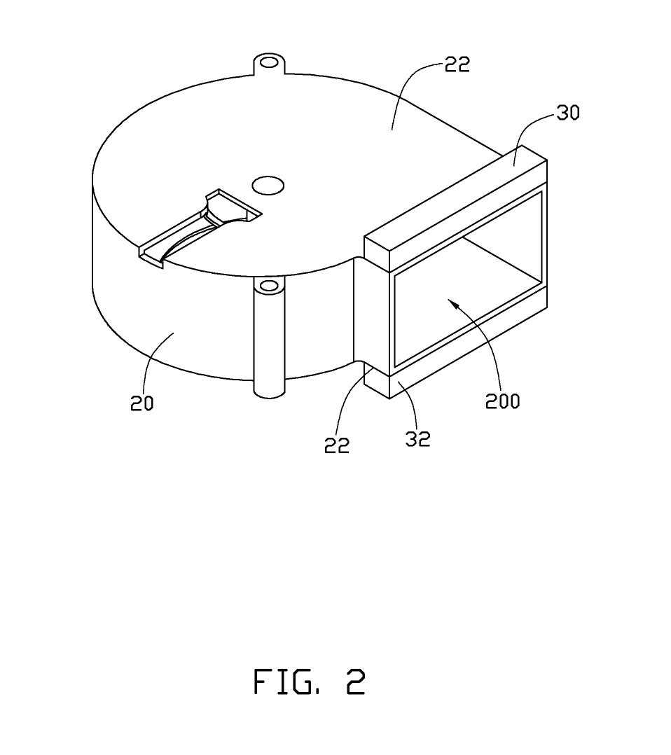

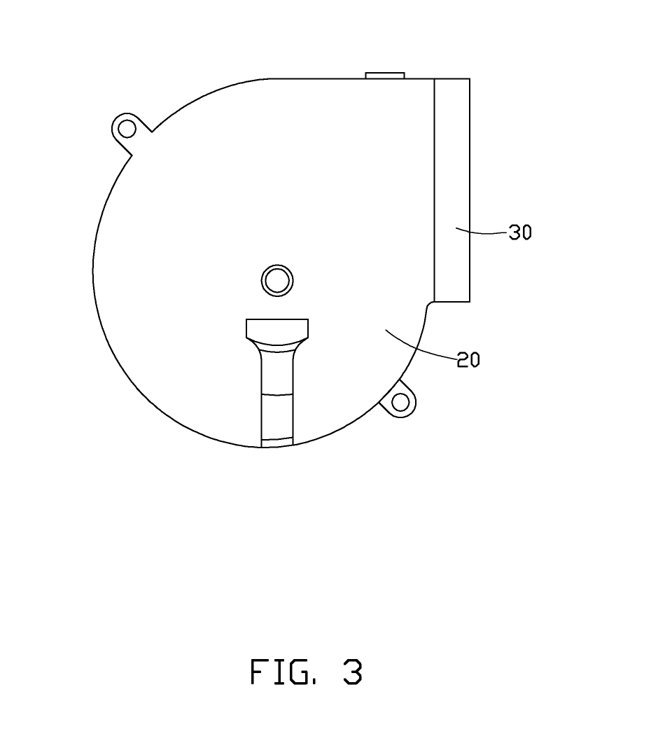

Referring to FIGS. 1-3, a first embodiment of an electronic device includes a chassis 10, a blower 20 received in the chassis 10, a first block 30, and a second block 32.

The chassis 10 includes a top surface 12, and a bottom surface 14 parallel to the top surface 12.

The blower 20 includes an upper surface 22, a lower surface 24 parallel to the upper surface 22, and an outlet 200 defined between the upper surface 22 and the lower surface 24. The blower 20 evacuates heat from inside the chassis 10 to the exterior.

The first block 30 is fixed on the upper surface 22 of the blower 20. The second block 32 is fixed on the lower surface 24 of the blower 20. The first block 30 and the second block 32 are positioned opposite to each other and to the outlet 200 of the blower 20. The first block 30 and the second block 32 can be made of thermally insulating material. The exterior surfaces of the first block 30 and the second block 32 can be plastic film, and the interior surfaces can be foams.

In use, the blower 20 is received in the chassis 10, the first block 30 abuts the top surface 12 of the chassis 10, and the second block 32 abuts the bottom surface 14 of the chassis 10. Therefore, the first block 30 is fixed between the top surface 12 and the upper surface 22, and the second block 32 is fixed between the bottom surface 14 and the lower surface 24. Accordingly, the first block 30 and the second block 32 fill gaps existing between the blower 20 and the chassis 10 to reduce recirculation.

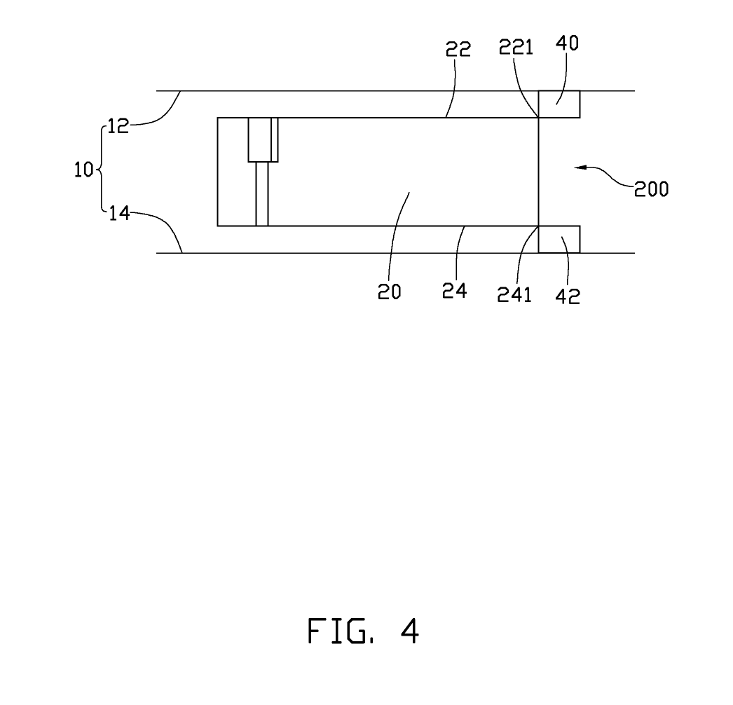

FIG. 4 is a schematic view according to a second embodiment, differing from FIG. 1 in that a first block 40 is fixed on the top surface 12 and abuts an upper portion 221 of the upper surface 22, and a second block 42 is fixed on the bottom surface 14 and abuts a lower portion 241 of the lower surface 24.

While the disclosure has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An electronic device comprising:
a chassis comprising a top surface and a bottom surface parallel to the top surface;
a blower received in the chassis, and wherein the blower comprises an upper surface, a lower surface parallel to the upper surface, and an outlet defined between the upper surface and the lower surface;
a first block disposed between the upper surface and the top surface to seal a gap between the upper surface and the top surface; and
a second block disposed between the lower surface and the bottom surface to seal a gap between the lower surface and the bottom surface.

2. The electronic device of claim 1, wherein the first block is fixed on the upper surface and the second block is fixed on the lower surface.

3. The electronic device of claim 2, wherein the first block and the second block are thermally insulating material.

4. The electronic device of claim 3, wherein exterior surfaces of the first block and second blocks are plastic film, and the interior surfaces are foams.

5. The electronic device of claim 1, wherein the first block is fixed on the top surface, and the second block is fixed on the bottom surface.

6. An electronic device comprising:
a chassis comprising a top surface and a bottom surface parallel to the top surface;
a blower received in the chassis, wherein the blower comprises an upper surface, a lower surface parallel to the upper surface, and an outlet defined between the upper surface and the lower surface;
a first block fixed on the top surface; and
a second block fixed on the bottom surface.

7. The electronic device of claim 6, wherein the first block and the second block are positioned opposite to each other and to the outlet of the blower.

8. The electronic device of claim 7, wherein the first block and the second block are thermally insulating material.

9. The electronic device of claim 8, wherein exterior surfaces of the first block and second blocks are plastic film, and the interior surfaces are foams.

10. The electronic device of claim 6, wherein the first block is fixed between the top surface and the upper surface, and the second block is fixed between the bottom surface and the lower surface.
